(19) United States
(12) Patent Application Publication
(10) Pub. No.: US 2014/0151825 A1
(43) Pub. Date: Jun. 5, 2014

(54) GIANT MAGNETO-RESISTIVE SENSOR AND MANUFACTURING METHOD THEREOF

(71) Applicant: SAMSUNG ELECTRO-MECHANICS CO., LTD., Suwon (KR)

(72) Inventors: Boum Seock Kim, Suwon (KR); Eun Tae Park, Suwon (KR); Se Hoon Jeong, Suwon (KR); Sung Ho Lee, Suwon (KR)

(73) Assignee: SAMSUNG ELECTRO-MECHANICS CO., LTD., Suwon (KR)

(21) Appl. No.: 13/831,703

(22) Filed: Mar. 15, 2013

(30) Foreign Application Priority Data
Nov. 30, 2012 (KR) 10-2012-0138443

(51) Int. Cl. H01L 29/82; H01L 43/12

(52) U.S. Cl. CPC H01L 29/82; H01L 43/12
USPC 257/421; 438/3

(57) ABSTRACT

Disclosed herein are a giant magneto-resistive sensor including a free layer stacked on a substrate and having a rotatable magnetic moment; a ferromagnetic fixed layer having a magnetic moment; a pin layer disposed neighboring the fixed layer; and a spacer layer disposed between the free layer and the fixed layer and having a roughness in an interface contacting the fixed layer, and a method of manufacturing the giant magneto-resistive sensor.

### CROSS REFERENCE TO RELATED APPLICATION

This application claims the benefit of Korean Patent Application No. 10-2012-0138443, filed on Nov. 30, 2012, entitled “Giant Magneto-Resistive Sensor and Manufacturing Method Thereof”, which is hereby incorporated by reference in its entirety into this application.

### BACKGROUND OF THE INVENTION

1. Technical Field

The present invention relates to a giant magneto-resistive sensor and a manufacturing method thereof.

2. Description of the Related Art

A terrestrial magnetism sensor measures an earth's magnetic field that is one of fine magnetic fields and indicates an orientation. A method of measuring the earth's magnetic field that is one of fine magnetic fields and indicating the orientation basically measures a third-axial component of the earth's magnetic field at a location horizontal to the surface of the earth and indicates the orientation.

As a single magnetic field detection method used by such a fine magnetic field detection sensor, a giant magneto-resistance (GMR) is used.

A GMR sensor using the above method can be mass-produced by fine patterning and has an excellent magnetic sensitivity, and thus the GMR sensor is used for various applications such as automobile, industry, medicine, and military, etc. as well as a mobile sensor.

A general example of the GMR sensor includes a fixed layer having magnetization is restricted to a predetermined direction and a free layer having a magnetization direction varying according to an external magnetic field.

That is, when the external magnetic field is applied, a GMR device exhibits a resistance according to a relative relation of the magnetization direction between the fixed layer and the free layer, and thus it is possible to detect the external magnetic field by measuring the resistance of the GMR device.

Meanwhile, a sensitivity of a sensor device is influenced by two factors, one is a thickness of a spacer layer disposed between the fixed layer and the free layer and second is an area of an interface between the spacer layer and the fixed layer.

In the case of the area of the sensor device, if the area is infinitely great, a size of the sensor device increases, and thus a general device increases the sensitivity of the sensor according to the thickness of the spacer layer.

However, there is a problem that such an increase in the thickness of the spacer layer does not meet the recent requirement of a light, thin, short, and small electronic device.

### PRIOR ART DOCUMENT

[Patent Document]
(Patent Document 1) Korean Patent Laid-Open Publication No. 2003-0036002

### SUMMARY OF THE INVENTION

The present invention has been made in an effort to provide a giant magneto-resistive sensor and a manufacturing method thereof that increase an area of an interface by giving a roughness to the interface.

According to a first preferred embodiment of the present invention, there is provided a giant magneto-resistive sensor including: a free layer stacked on a substrate and having a rotatable magnetic moment; a ferromagnetic fixed layer having a magnetic moment; a pin layer disposed neighboring the fixed layer; and a spacer layer disposed between the free layer and the fixed layer and having a roughness in an interface contacting the fixed layer.

The free layer having a double layer structure may include: a first ferromagnetic layer disposed neighboring the substrate; and a second ferromagnetic layer disposed neighboring the spacer layer.

The first ferromagnetic layer may be a NiFe layer, and the second ferromagnetic layer may be a CoFe layer.

A thickness of the first ferromagnetic layer may be in the range of about 20 Å and about 100 Å, and a thickness of the second ferromagnetic layer may be in the range of about 5 Å and about 25 Å.

The fixed layer may be an artificial semi-ferromagnetic magnet.

The artificial semi-ferromagnetic magnet may include: a first ferromagnetic layer disposed neighboring the spacer layer; and a second ferromagnetic layer disposed neighboring the pin layer.

The giant magneto-resistive sensor may further include: a coupling layer disposed between the first ferromagnetic layer and the second ferromagnetic layer.

The first ferromagnetic layer and the second ferromagnetic layer may be CoFe layers, and the coupling layer may be a ruthenium layer.

Thicknesses of the first ferromagnetic layer and the second ferromagnetic layer may be in the range of about 15 Å and about 40 Å, and a thickness of the coupling layer may be in the range of about 8 Å and about 12 Å.

A thickness of the fixed layer may be in the range of about 20 Å and about 30 Å.

A thickness of the pin layer may be in the range of about 100 Å and about 300 Å.

The roughness of the spacer layer may be a conical shape.

According to a second preferred embodiment of the present invention, there is provided a method of manufacturing a giant magneto-resistive sensor, the method including: (A) depositing a free layer formed of a ferromagnetic material having a magnetic moment on a substrate; (B) depositing a spacer layer formed of a non-magnetic material on the free layer; (C) forming a roughness on the spacer layer; (D) depositing a fixed layer formed of the ferromagnetic material having a magnetic moment on the spacer layer; and (E) depositing a pin layer on the fixed layer.

Operation (A) may include: (A-1) forming a first ferromagnetic layer disposed neighboring the substrate; and (A-2) forming a second ferromagnetic layer disposed neighboring the first ferromagnetic layer.

Operation (C) may include: forming a roughness on the spacer layer by using ion beam etching.

The roughness formed in operation (C) may be a conical shape.

Operation (D) may include: (D-1) forming a first ferromagnetic layer disposed neighboring the spacer layer; and (D-2) forming a second ferromagnetic layer disposed neighboring the first ferromagnetic layer.

Operation (D) may further include (D-3) forming a coupling layer between the first ferromagnetic layer and the second ferromagnetic layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a giant magneto-resistive sensor according to an embodiment of the present invention;

FIG. 2 is a graph of a variation of the giant magneto-resistive sensor of FIG. 1 when a varying magnetic field exists;

FIG. 3 is a plan view of a giant magneto-resistive sensor according to another embodiment of the present invention; and

FIG. 4 is a flowchart of a method of manufacturing a giant magneto-resistive sensor according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 1 is a plan view of a giant magneto-resistive sensor 10 according to an embodiment of the present invention.

Referring to FIG. 1, the giant magneto-resistive sensor 10 according to an embodiment of the present invention includes a substrate 12, a free layer 14, a spacer layer 16, a fixed layer 18, and a pin layer 20.

Devices consisting of an array including the giant magneto-resistive sensor 10 such as a transistor and a memory are formed inside of the substrate 12 or on the substrate 12. A wire layer is also included in the substrate 12.

The wire layer forms a giant magneto-resistive sensor array by connecting devices, pads, and the giant magneto-resistive sensor 10.

The pads connect the giant magneto-resistive sensor array and an external equipment through an Au wire bonded on upper surfaces of the pads. The wire layer may be referred to as a conductor line.

The free layer 14 includes a first ferromagnetic layer 22, preferably NiFe and a second ferromagnetic layer 24, more preferably, CoFe. The first ferromagnetic layer 22 is disposed neighboring a dielectric layer 10b.

The first ferromagnetic layer 22 of the free layer 14 is formed preferably in the range of about Ni(85)Fe(15) and about Ni(80.5)Fe(19.5), and more preferably approximately Ni(82)Fe(18). Numbers in brackets indicate component ratios (this applies below).

A thickness of the first ferromagnetic layer 22 of the free layer 14 is preferably in the range of about 20 Å and about 100 Å, and more preferably 30 Å.

Also, the second ferromagnetic layer 24 of the free layer 14 is preferably approximately Co(90)Fe(10).

A thickness of the second ferromagnetic layer 24 of the free layer 14 is preferably in the range of about 5 Å and about 25 Å, and more preferably 13 Å.

Next, the spacer layer 16 is formed of a non-magnetic material, preferably copper, and is disposed between the free layer 14 and the fixed layer 18.

In the present invention, a roughness R is applied to a surface of the spacer layer 16 contacting the fixed layer 18 and thus an area of an interface between the spacer layer 16 and the fixed layer 18 increases.

In this regard, the roughness R applied to the spacer layer 16 is a conical shape as shown in an expanded view.

A thickness of the spacer layer 16 is preferably in the range of about 20 Å and about 35 Å, and more preferably approximately 24 Å.

Meanwhile, the fixed layer 18 is formed of a ferromagnetic material, preferably CoFe, and adjoins the pin layer 20.

Magnetization of the fixed layer 18 is fixed in a previously set direction, whereas magnetization of the free layer 14 freely rotates in correspondence to an external magnetic field of a magnetic medium.

The magnetization direction of the fixed layer 18 is fixed by the pin layer 20 that is coupled to the fixed layer 18.

The fixed layer 18 is formed preferably approximately Co(90)Fe(10). A thickness of the fixed layer 18 is preferably in the range of about 18 Å and about 30 Å, and more preferably approximately 25 Å.

Next, the pin layer 20 is formed of an alloy mainly including Mn, for example, PtMnX. In this regard, X is Cr or Pd. The pin layer 20 has a blocking temperature of about 380° C., and has an annealing temperature of about 270° C.

When PtMnCr is used, the pin layer 20 is formed preferably in the range of about Pt(36)Mn(64)Cr(>0) and about Pt(48)Mn(51)Cr(1), more preferably approximately Pt(44)Mn(55.5)Cr(0.5). In this case, a thickness of the pin layer 20 is preferably in the range of about 100 Å and about 300 Å, and more preferably approximately 200 Å.

When PtMnPd is used, the pin layer 20 is formed preferably in the range of about Pt(15)Mn(50)Pd(35) and about Pt(25)Mn(50)Pd(25), more preferably approximately Pt(20)Mn(50)Pd(30). In this case, a thickness of the pin layer 20 is preferably in the range of about 150 Å and about 300 Å, and more preferably approximately 250 Å.

A resistance of the giant magneto-resistive sensor 10 varies as a function with respect to an angle formed between the magnetization direction of the free layer 14 and the magnetization direction of the fixed layer 18.

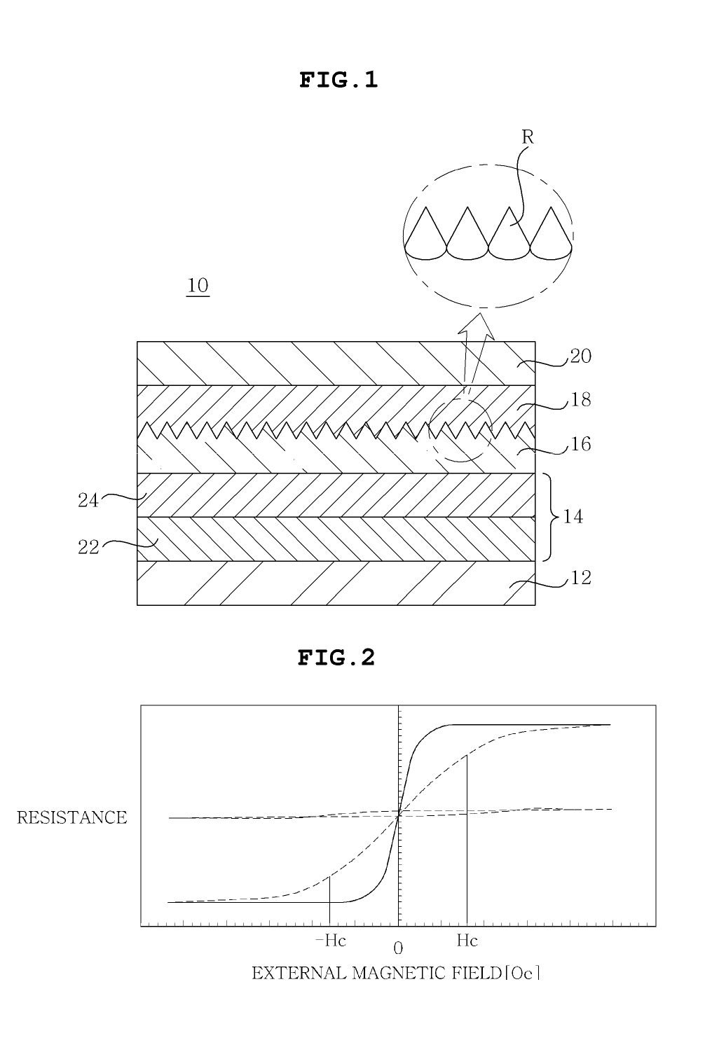

As indicated in a straight line of FIG. 2, in a case where the varying external magnetic field exists, the resistance of the giant magneto-resistive sensor 10 substantially varies in proportional to the external magnetic field within a range of −Hc and +Hc.

In the present invention, the roughness R is applied to a surface of the spacer layer 16 contacting the fixed layer 18 and thus the area of the interface between the spacer layer 16 and the fixed layer 18 increases. As a result, a sensitivity is excellent and a response characteristic is good compared to a conventional giant magneto-resistive sensor indicated in a broken line of FIG. 2.

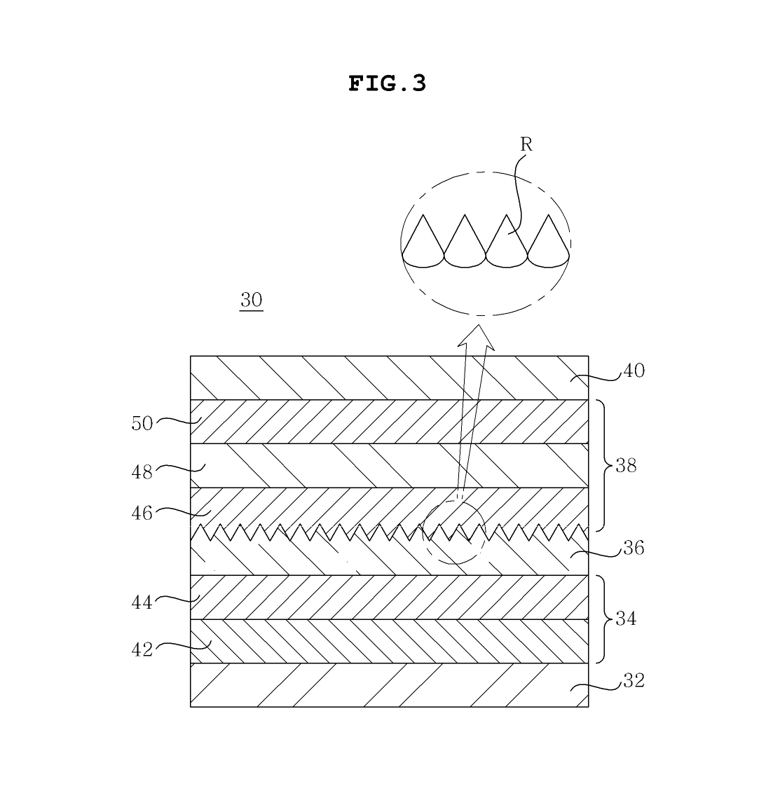

FIG. 3 is a plan view of a giant magneto-resistive sensor 30 according to another embodiment of the present invention.

Referring to FIG. 3, the giant magneto-resistive sensor 30 according to another embodiment of the present invention includes a substrate 32, a free layer 34, a spacer layer 36, a fixed layer 38, and a pin layer 40.

The giant magneto-resistive sensor 30 according to another embodiment of the present invention is similar to the giant magneto-resistive sensor 10 according to an embodiment of the present invention, except that the fixed layer 38 further includes preferably a coupling layer 48 that is formed of ruthenium and disposed between first and second ferromagnetic layers 46 and 50.

In this regard, the first and second ferromagnetic layers 46 and 50 of the fixed layer 38 are formed of preferably approximately Co(90)Fe(10). Thicknesses of the first and second ferromagnetic layers 46 and 50 of the fixed layer 38 are preferably in the range of about 18 Å and about 40 Å, and more preferably in the range of about 25 Å and about 30 Å.

Also, a thickness of the coupling layer 48 of the fixed layer 38 is preferably in the range of about 8 Å and about 12 Å.

As described above, the giant magneto-resistive sensor 30 according to another embodiment of the present invention is similar to the giant magneto-resistive sensor 10 according to an embodiment of the present invention, except that the fixed layer 38 further includes preferably the coupling layer 48 that is formed of ruthenium and disposed between the first and second ferromagnetic layers 46 and 50. Thus, detailed descriptions of the elements excluding the difference are omitted there.

A resistance of the giant magneto-resistive sensor 30 varies as a function with respect to an angle formed between a magnetization direction of the free layer 34 and a magnetization direction of the fixed layer 34.

In a case where a varying external magnetic field exists, the resistance of the giant magneto-resistive sensor 30 substantially varies in proportional to the external magnetic field within a range of −Hc and +Hc.

In the present invention, the roughness R is applied to a surface of the spacer layer 36 contacting the fixed layer 38 and thus the area of the interface between the spacer layer 36 and the fixed layer 38 increases. As a result, a sensitivity is excellent and a response characteristic is good compared to a giant magneto-resistive sensor according to a conventional art.

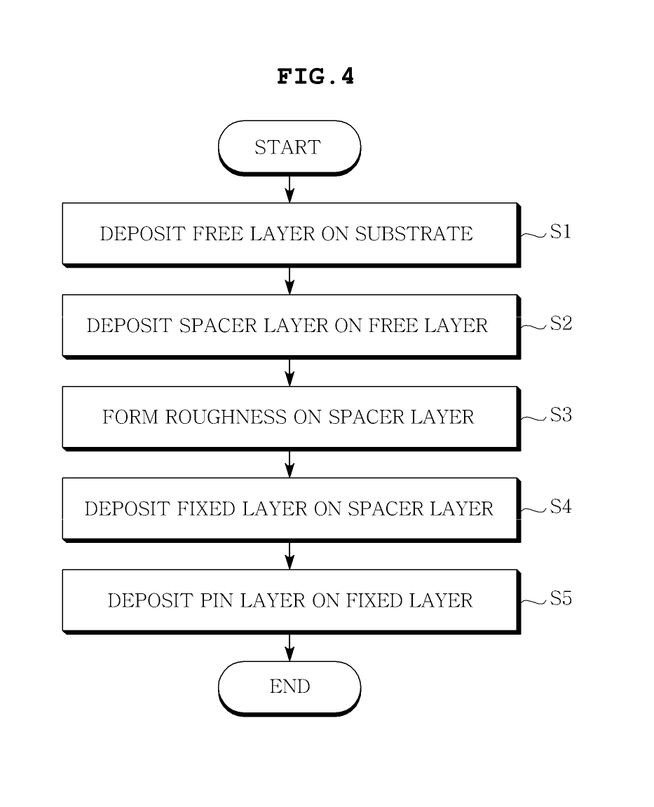

FIG. 4 is a flowchart of a method of manufacturing a giant magneto-resistive sensor according to an embodiment of the present invention.

As shown in FIG. 4, the method includes an operation S1 of depositing a free layer formed of a ferromagnetic material having a magnetic moment on a substrate, an operation S2 of depositing a spacer layer formed of a non-magnetic material on the free layer, an operation S3 of forming a roughness on the spacer layer, an operation S4 of depositing a fixed layer formed of the ferromagnetic material having a magnetic moment on the spacer layer, and an operation S5 of depositing a pin layer on the fixed layer.

The operation S1 of depositing the free layer formed on the substrate may be performed by using, for example, a magnetron sputter. In this case, an initial vacuum degree maintains a vacuum degree below 10-7 Torr, injects a plasma generation gas such as Ar, and performs a process at about 10-3 Torr and about 10-2 Torr.

In this regard, first and second ferromagnetic layers may be sequentially formed. The first ferromagnetic layer includes preferably NiFe. The second ferromagnetic layer includes preferably CoFe. The first ferromagnetic layer is disposed neighboring a dielectric layer.

The first ferromagnetic layer of the free layer is formed preferably in the range of about Ni(85)Fe(15) and about Ni(80.5)Fe(19.5), and more preferably approximately Ni(82)Fe(18).

A thickness of the first ferromagnetic layer of the free layer is preferably in the range of about 20 Å and about 100 Å, and more preferably 30 Å.

The second ferromagnetic layer of the free layer is preferably approximately Co(90)Fe(10). A thickness of the second ferromagnetic layer of the free layer is preferably in the range of about 5 Å and about 25 Å, and more preferably 13 Å.

The operation S2 of depositing the spacer layer on the free layer is performed by forming the non-magnetic material on the free layer. For example, Cu or Ag may be used.

The operation S3 of forming the roughness on the spacer layer is performed by forming the roughness such as a conical shape on the spacer layer. The roughness is formed by etching the spacer layer by ion beam etching.

The operation S4 of depositing the fixed layer on the spacer layer is similar to the operation of forming the free layer on the substrate, and may be performed by using a magnetron sputter.

Preferably, the first and second ferromagnetic layers that are formed of CoFe may be sequentially formed. In a case where a coupling layer is disposed, after the first ferromagnetic layer is firstly formed, the coupling layer that is formed of ruthenium is formed and then the second ferromagnetic layer may be formed.

The operation S5 of depositing the pin layer on the fixed layer is performed by depositing the non-magnetic material by using a sputtering equipment on the spacer layer. In this regard, the deposited non-magnetic material is PtMnX. In this regard, X is Cr or Pd.

When PtMnCr is used, the pin layer is formed preferably in the range of about Pt(36)Mn(64)Cr(>0) and about Pt(48)Mn(51)Cr(1), more preferably approximately Pt(44)Mn(55.5)Cr(0.5).

In this case, a thickness of the pin layer is preferably in the range of about 100 Å and about 300 Å, and more preferably approximately 200 Å.

Unlike this, when PtMnPd is used, the pin layer is formed preferably in the range of about Pt(15)Mn(50)Pd(35) and about Pt(25)Mn(50)Pd(25), more preferably approximately Pt(20)Mn(50)Pd(30). In this case, a thickness of the pin layer is preferably in the range of about 150 Å and about 300 Å, and more preferably approximately 250 Å.

A resistance of the giant magneto-resistive sensor formed through the above process varies as a function with respect to an angle formed between a magnetization direction of the free layer and a magnetization direction of the fixed layer.

In a case where a varying external magnetic field exists, the resistance of the giant magneto-resistive sensor substantially varies in proportional to the external magnetic field within a range of −Hc and +Hc.

In the present invention, the roughness R is applied to a surface of the spacer layer contacting the fixed layer and thus the area of the interface between the spacer layer and the fixed layer increases. As a result, a sensitivity is excellent and a response characteristic is good compared to a giant magneto-resistive sensor according to a conventional art.

According to the embodiments of the present invention, an area of an interface increases by giving a roughness to the interface, and thus a further enhanced sensitivity may be obtained.

As a result, an increase in a thickness of a spacer layer is unnecessary for enhancing the sensitivity, and thus a recent requirement of a light, thin, short, and small electronic device may be met.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A giant magneto-resistive sensor comprising:
a free layer stacked on a substrate and having a rotatable magnetic moment;
a ferromagnetic fixed layer having a magnetic moment;
a pin layer disposed neighboring the fixed layer; and
a spacer layer disposed between the free layer and the fixed layer and having a roughness in an interface contacting the fixed layer.

2. The giant magneto-resistive sensor as set forth in claim 1, wherein the free layer has a double layer structure including:
a first ferromagnetic layer disposed neighboring the substrate; and
a second ferromagnetic layer disposed neighboring the spacer layer.

3. The giant magneto-resistive sensor as set forth in claim 2, wherein the first ferromagnetic layer is a NiFe layer, and
wherein the second ferromagnetic layer is a CoFe layer.

4. The giant magneto-resistive sensor as set forth in claim 3, wherein a thickness of the first ferromagnetic layer is in the range of about 20 Å and about 100 Å, and
wherein a thickness of the second ferromagnetic layer is in the range of about 5 Å and about 25 Å.

5. The giant magneto-resistive sensor as set forth in claim 1, wherein the fixed layer is an artificial semi-ferromagnetic magnet.

6. The giant magneto-resistive sensor as set forth in claim 5, wherein the artificial semi-ferromagnetic magnet includes:
a first ferromagnetic layer disposed neighboring the spacer layer; and
a second ferromagnetic layer disposed neighboring the pin layer.

7. The giant magneto-resistive sensor as set forth in claim 6, further comprising: a coupling layer disposed between the first ferromagnetic layer and the second ferromagnetic layer.

8. The giant magneto-resistive sensor as set forth in claim 7, wherein the first ferromagnetic layer and the second ferromagnetic layer are CoFe layers, and
wherein the coupling layer is a ruthenium layer.

9. The giant magneto-resistive sensor as set forth in claim 8, wherein thicknesses of the first ferromagnetic layer and the second ferromagnetic layer are in the range of about 15 Å and about 40 Å, and
wherein a thickness of the coupling layer is in the range of about 8 Å and about 12 Å.

10. The giant magneto-resistive sensor as set forth in claim 1, wherein a thickness of the fixed layer is in the range of about 20 Å and about 30 Å.

11. The giant magneto-resistive sensor as set forth in claim 1, wherein a thickness of the pin layer is in the range of about 100 Å and about 300 Å.

12. The giant magneto-resistive sensor as set forth in claim 1, wherein the roughness of the spacer layer is a conical shape.

13. A method of manufacturing a giant magneto-resistive sensor, the method comprising:
(A) depositing a free layer formed of a ferromagnetic material having a magnetic moment on a substrate;
(B) depositing a spacer layer formed of a non-magnetic material on the free layer;
(C) forming a roughness on the spacer layer;
(D) depositing a fixed layer formed of the ferromagnetic material having a magnetic moment on the spacer layer; and
(E) depositing a pin layer on the fixed layer.

14. The method as set forth in claim 13, wherein operation (A) includes:
(A-1) forming a first ferromagnetic layer disposed neighboring the substrate; and
(A-2) forming a second ferromagnetic layer disposed neighboring the first ferromagnetic layer.

15. The method as set forth in claim 13, wherein operation (C) includes: forming a roughness on the spacer layer by using ion beam etching.

16. The method as set forth in claim 13, wherein the roughness formed in operation (C) is a conical shape.

17. The method as set forth in claim 13, wherein operation (D) includes:
(D-1) forming a first ferromagnetic layer disposed neighboring the spacer layer; and
(D-2) forming a second ferromagnetic layer disposed neighboring the first ferromagnetic layer.

18. The method as set forth in claim 17, wherein operation (D) further includes (D-3) forming a coupling layer between the first ferromagnetic layer and the second ferromagnetic layer.
